(19) United States
(12) Patent Application Publication
(10) Pub. No.: US 2013/0127454 A1
(43) Pub. Date: May 23, 2013

(54) MAGNETIC FIELD SENSOR INCLUDING AN ANISOTROPIC MAGNETORESISTIVE MAGNETIC SENSOR AND A HALL MAGNETIC SENSOR

(71) Applicant: STMicroelectronics S.r.I., Agrate Brianza (IT)

(72) Inventors: Tommaso Ungaretti, Pavia (IT); Benedetto Vigna, Potenza (IT); Fabio Bottinelli, Malnate (VA) (IT)

(73) Assignee: STMicroelectronics S.e.I., Agrate Brianza (IT)

(21) Appl. No.: 13/683,922

(22) Filed: Nov. 21, 2012

(30) Foreign Application Priority Data
Nov. 22, 2011 (IT) TO2011A001072

(51) Int. Cl. G01R 33/09; H01L 43/14; G01R 33/07

(52) U.S. Cl. CPC G01R 33/096; G01R 33/07; H01L 43/14
USPC 324/251; 438/3

(57) ABSTRACT

A magnetic field sensor, including a Hall magnetic sensor, formed within a first die and configured to detect a first magnetic field, and a first anisotropic magnetoresistive magnetic sensor, having a first anisotropic magnetoresistive transducer, formed within a second die and configured to generate an electrical measurement quantity as a function of a second magnetic field. An electronic reading circuit formed within the first die, is electrically connected to the first anisotropic magnetoresistive transducer, and provides a first measure indicating the second magnetic field, on the basis of the electrical measurement quantity. The first and second dice are fixed with respect to one another and have main surfaces parallel to the same reference plane. The first magnetic field being oriented in a first direction perpendicular to the reference plane and the second magnetic field being oriented in a second direction parallel to the reference plane.

### BACKGROUND

1. Technical Field

The present disclosure relates to a magnetic field sensor; in particular, a magnetic field sensor including an anisotropic magnetoresistive (AMR) magnetic sensor and a Hall magnetic sensor.

2. Description of the Related Art

As is known, today available are numerous magnetic field sensors, also known, in brief, as “magnetic sensors”.

Magnetic field sensors enable detection of natural magnetic fields (for example, the Earth's magnetic field) and magnetic fields generated by electrical components (such as electrical or electronic devices and lines traversed by electric current); i.e., they generate output signals indicating these magnetic fields.

Magnetic field sensors are widely used in a vast range of applications. In particular, magnetic field sensors are today used within numerous systems, such as for example compasses, systems for detecting ferrous materials, systems for detecting currents, etc.

In detail, there exist a wide range of types of magnetic field sensors. For example, currently widespread are magnetic field sensors based upon the Hall effect, which are commonly referred to as “Hall magnetic sensors” or else, more in brief, as “Hall sensors”.

As shown in FIG. 1, a Hall sensor 1 is formed in general by a well 2 of semiconductor material, formed within a die 4 and typically having a doping of an N type. In greater detail, in top plan view, the well 2 may have, for example, a square or rectangular shape. Furthermore, in use, the die 4 is biased in such way that the well 2 is traversed by a current I, which flows in a way substantially parallel to a main surface of the die 4, designated by S.

In particular, the well 2 is in electrical contact with a first biasing terminal and a second biasing terminal, designated, respectively, by 6 and 8 and made, for example, of metal material, as well as with a first reading terminal and a second reading terminal, which are designated, respectively, by 10 and 12 and are also made, for example, of metal material. Generally, the first and second biasing terminals 6, 8 and the first and second reading terminals 10, 12 are formed on the main surface S of the die 4, so as to contact the well 2.

Moreover formed within the die 4 are a biasing circuit 14 and a reading circuit 16.

The biasing circuit 14 is electrically connected to the first and second biasing terminals 6, 8, and is designed to generate the current I in such a way that it flows between the first and second biasing terminals 6, 8. In practice, the current I flows between two opposite sides of the well 2, and perpendicular with respect thereto, i.e., parallel with respect to the other two sides of the well 2. Instead, the reading circuit 16 is electrically connected to the first and second reading terminals 10, 12.

In the presence of an external magnetic field B directed perpendicular with respect to the main surface S of the die 4, and hence orthogonal to the well 2, by the Hall effect a voltage is generated across the two sides of the well 2 arranged parallel with respect to the current I, and hence across the first and second reading terminals 10, 12; said voltage is a function of the external magnetic field. The Hall sensor 1, and in particular the reading circuit 16, is designed to process this voltage in such a way as to supply a quantity, alternatively analog or digital, indicating the external magnetic field.

For practical purposes, the Hall sensor 1 detects magnetic fields oriented in a direction perpendicular to the main surface S of the die 4. In greater detail, if we assume an orthogonal reference system xyz in which the axes x and y lie in a plane parallel to the main surface S of the die 4, and in which the axis z is perpendicular to the main surface S of the die 4, the Hall sensor 1 is able to detect and determine magnetic fields directed along the axis z.

In addition, the Hall sensor 1 may be produced by providing the respective well 2 made of semiconductor material by means of so-called CMOS (complementary metal-oxide semiconductor) processes of a traditional type.

Likewise available are magnetic field sensors generally known as “anisotropic magnetoresistive” (AMR) magnetic sensors, which are based upon the phenomenon of anisotropic magnetoresistivity.

In detail, the phenomenon of anisotropic magnetoresistivity occurs within so-called magnetoresistive materials, i.e., within particular ferrous materials that, when subjected to an external magnetic field, undergo a variation of resistivity as a function of the characteristics of the external magnetic field.

In particular, given a magnetoresistive element made of a magnetoresistive material and traversed by a current, and if 8 is the angle that is formed between the direction of magnetization of the magnetoresistive element and the direction of the current, the effective value of resistivity of the magnetoresistive element depends upon the angle θ. Consequently, as the value of the angle θ varies, the value of electrical resistance of the magnetoresistive element varies. In particular, when the angle θ is zero, i.e., when the direction of magnetization is parallel to the direction of the current, the magnetoresistive element has a maximum resistance. Instead, when the angle θ is 90°, i.e., when the direction of magnetization is perpendicular to the direction of the current, the magnetoresistive element has a minimum resistance.

In other words, if we assume the current to be constant, across the magnetoresistive element a voltage is generated that varies as a function of the angle θ. Since the direction of magnetization of the magnetoresistive element depends upon a possible external magnetic field present in the proximity of the magnetoresistive element, the voltage that is set up across the magnetoresistive element indicates this external magnetic field. This voltage can thus be measured and used for determining the direction and intensity of the external magnetic field.

AMR sensors hence include within them at least one magnetoresistive element, which is typically formed by a thin film. Moreover, in order to improve the sensitivity, known to the art are techniques that enable alignment, prior to use, of the magnetic domains present within the magnetoresistive element so as to define a preferred direction of orientation, also known as easy axis. Assuming that the magnetoresistive element has a prevalent dimension, typically the preferred direction of orientation is set in such a way that it is parallel to the prevalent dimension of the magnetoresistive element.

Likewise known are techniques that enable biasing of the AMR sensors in such a way that, in the absence of external magnetic fields, the direction of the current and the direction of magnetization form an angle substantially equal to 45° or 135° so as to optimize the sensitivity and linearity.

Likewise known are AMR sensors that each comprise four magnetoresistive elements, which are arranged so as to form a bridge structure, for example a Wheatstone bridge. In particular, as shown at the level of equivalent electrical circuit in FIG. 2, which represents a Wheatstone bridge 19, the magnetoresistive elements (designated by 20) of the Wheatstone bridge 19 ideally have one and the same value of resistance and are such as to form two diagonal pairs of equal elements, the magnetic elements of one pair and the other reacting in an opposite way to the external magnetic fields. In particular, in FIG. 2, I is the current that flows in the magnetoresistive elements 20, whilst R is the common value of resistance.

In the presence of an external magnetic field Hₑ, if a supply voltage Vₛ is applied to the Wheatstone bridge 19, and in particular across the first two terminals of the Wheatstone bridge 19 (designated by 22 and 24), which function as first and second input terminals, a variation of resistance AR (in absolute value) of the magnetoresistive elements 20 is set up, as well as a corresponding variation of the value of voltage drop on said magnetoresistive elements 20. In fact, the external magnetic field Hₑ determines a variation of the direction of magnetization of the magnetoresistive elements 20, with consequent unbalancing of the Wheatstone bridge 19. This unbalancing results in a variation of voltage ΔV at output from the Wheatstone bridge 19, and in particular across the two remaining terminals of the Wheatstone bridge 19 (designated by 26 and 28), which function as first and second output terminals. On the basis of this voltage variation ΔV it is thus possible to determine the external magnetic field Hₑ.

In detail, the voltage variation ΔV is received and processed, in order to determine a quantity indicating the external magnetic field, by a reading circuit (not shown). Generally, whereas the Wheatstone bridge 19, and hence the magnetoresistive elements 20, are formed in a first die, the reading circuit is formed in a second die, possibly together with an appropriate circuit designed to generate the supply voltage V. This is due to the fact that integration, within one and the same die, of the magnetoresistive elements 20 and of the reading circuit may prove technologically problematical, requiring non-standard operations.

In greater detail, if reference is made to an AMR transducer to indicate a portion of the AMR sensor that includes the magnetoresistive elements but is without the reading circuit and the circuit designed to generate the supply voltage Vₛ, the AMR transducer is usually formed in the first die, which is connected to the second die, for example by wire bonding, or else by means of techniques known as “flip chip” techniques.

In addition, the magnetoresistive elements of the AMR transducer, and hence also the AMR sensor, are arranged in such a way that the transducer is sensitive to magnetic fields directed parallel with respect to the main surface of the first die.

Likewise known are magnetic sensors with a number of axes, such as for example magnetic sensors with three axes (also known as “triaxial magnetic sensors”), which enable detection of magnetic fields directed along any one of three different axes, perpendicular to one another.

In general, there exist substantially two families of triaxial sensors: triaxial sensors of a Hall-effect type, and triaxial sensors of an AMR type.

As regards, in particular, triaxial sensors of a Hall-effect type, the so-called “concentrator sensors” are known, described, for example, in “CMOS Three Axis Hall Sensor and Joystick Application”, Proceedings of Sensors 2004, IEEE, vol. 2, pp. 977-980.

In detail, a concentrator sensor is formed within a respective die and comprises a respective magnetic concentrator, formed in the case in point by a layer of ferromagnetic material. Moreover formed within the die are at least four Hall structures of a traditional type, which are arranged underneath the concentrator, and in particular in the proximity of the edge of the concentrator and at the vertices of a rhombus, i.e., to form a cross. In detail, each of the four Hall structures includes a respective well of semiconductor material, as well as a respective pair of biasing terminals and a respective pair of reading terminals, and enables, in a way similar to what has been described previously in connection with the Hall sensors, determination of a corresponding voltage indicating a possible magnetic field.

The concentrator sensor further comprises a respective electronic circuit, integrated in the die and connected to the four Hall structures, which enables determination of the magnetic fields oriented both in a parallel direction and in a perpendicular direction with respect to the main surface of the die, on the basis of the voltages supplied by the four Hall structures.

In greater detail, operation of the concentrator sensors is based upon the fact that, in the case where the concentrator sensor is in the presence of a magnetic field directed parallel with respect to the main surface of its own die, the field lines of this magnetic field bend in an area corresponding to the magnetic concentrator, traversing the Hall structures. More in particular, at a distance from the magnetic concentrator, the field lines are parallel to the main surface of the die. Instead, in the proximity of the magnetic concentrator, the field lines bend so as to traverse the magnetic concentrator and, consequently, also the Hall structures, thanks to the arrangement assumed by the Hall structures with respect to the magnetic concentrator. In practice, in the proximity of the magnetic concentrator the field lines are substantially orthogonal to the main surface of the die; hence, they can be detected by the Hall structures.

Concentrator sensors present the advantage of enabling measurement of magnetic fields directed along three different axes, using a single die. However, the production of the concentrator requires execution of non-standard technological processes with respect to traditional CMOS processes. In addition, the four Hall structures, which are basically four Hall sensors, do not have particularly high sensitivities, and are hence not suited for applications of a compass type. Once again, it is possible, in use, for the magnetic concentrators to be magnetized in a permanent way, for example on account of particularly intense magnetic fields, in which case there occurs a variation of sensitivity and/or an increase of non-linearity.

As regards, instead, triaxial sensors of an AMR type, each of them is formed in general by three dice, fixed with respect to one another and housed within one and the same package. An example of triaxial sensor of an AMR type is shown in FIG. 3, where it is designated by 30.

The triaxial sensor of an AMR type shown in FIG. 3 is enclosed in a respective package (not shown) and comprises a first die, a second die, and a third die, designated respectively by 32, 34, and 36, as well as a support 38, made, for example, of organic resin and including vias and paths of conductive material (not shown). The support 38 performs the function of carrying the first, second, and third dice 32-34-36, in addition to enabling electrical connection of the triaxial sensor of an AMR type 30 with the outside world. For this purpose, the bottom surface of the support 38 has a plurality of pads, not shown.

In detail, formed within the first die 32 are a first AMR transducer 40 and a second AMR transducer 41, i.e., a first electronic circuit and a second electronic circuit, each including at least one magnetoresistive element (not shown) and designed to supply on a respective pair of output terminals a respective voltage indicating a magnetic field. Likewise formed within the second die 34 is a third AMR transducer 42. Moreover formed within the third die 36 is an electronic reading and biasing circuitry 44.

In greater detail, the support 38 carries the second and third dice 34, 36, to which it is electrically connected, respectively, by means of a plurality of contacts 48, made of a bonding paste, and a first plurality of wire bondings 50. In addition, the third die 36 carries the first die 32, to which it is electronically connected by means of a second plurality of wire bondings 52; in addition, the third die 36 is electrically connected to the second die 34 through the first plurality of wire bondings 50, the support 38, and the plurality of contacts 48.

In this way, the electronic reading and biasing circuitry 44 is connected to the first, second, and third AMR transducers 40-42. Moreover, the electronic reading and biasing circuitry 44 supplies the first, second, and third AMR transducers 40-42 and receives the voltages generated thereby. By processing these voltages, the electronic reading and biasing circuitry 44 is able to supply an analog or digital signal indicating the magnetic fields present in an area corresponding to the first, second, and third AMR transducers 40-42.

In still greater detail, assuming that the reference system xyz is fixed with respect to the support 38 and that it is such that the plane xy is parallel to a main surface of the support 38 itself, the arrangement of the first and second dice 32-34, as well as the arrangement of the first, second, and third AMR transducers 40-42, or rather the arrangement of the magnetoresistive elements of the first, second, and third AMR transducers 40-42 is such that the voltages supplied by the first, second, and third AMR transducers 40-42 are a function of magnetic fields directed, respectively, along the axis x, the axis y, and the axis z. For practical purposes, the first and second dice 32, 34 are arranged perpendicular to one another; i.e., the respective main surfaces are perpendicular to one another.

The triaxial sensor of an AMR type 30 is characterized by high sensitivity. However, since the first and second dice 32, 34 are set at 90°, it presents a high complexity of assembly and moreover requires a package having considerable overall dimensions.

### BRIEF SUMMARY

The present disclosure is directed to a magnetic field sensor that includes a first die having a first surface in a reference plane, a Hall magnetic sensor formed in the first die and configured to detect a first magnetic field having an orientation in a first direction perpendicular to the reference plane, and a second die having a second surface in the same reference plane as the first die and being parallel to the first surface of the first die, the second die being fixed with respect to the first die. The sensor also includes a first anisotropic magnetoresistive magnetic sensor that has a first anisotropic magnetoresistive transducer formed in the second die configured to generate a first electrical measurement quantity as a function of a second magnetic field, the second magnetic field having an orientation in a second direction parallel to the reference plane and an electronic reading circuit formed in the first die, electrically connected to the first anisotropic magnetoresistive transducer, and configured to provide a first measure indicative of the second magnetic field based on the first electrical measurement quantity.

### BRIEF DESCRIPTION OF THE SEVERAL VIEWS OF THE DRAWINGS

For a better understanding of the present disclosure, preferred embodiments thereof are now described, purely by way of non-limiting example, with reference to the attached drawings, wherein:

FIG. 1 is a schematic perspective view of a Hall sensor of a known type;

FIG. 2 shows an equivalent electrical circuit of a Wheatstone-bridge AMR sensor;

FIG. 3 is a schematic illustration of a perspective view of a triaxial magnetic sensor of an AMR type; and

FIGS. 4, 5 and 6 are schematic perspective views of embodiments of the present magnetic field sensor.

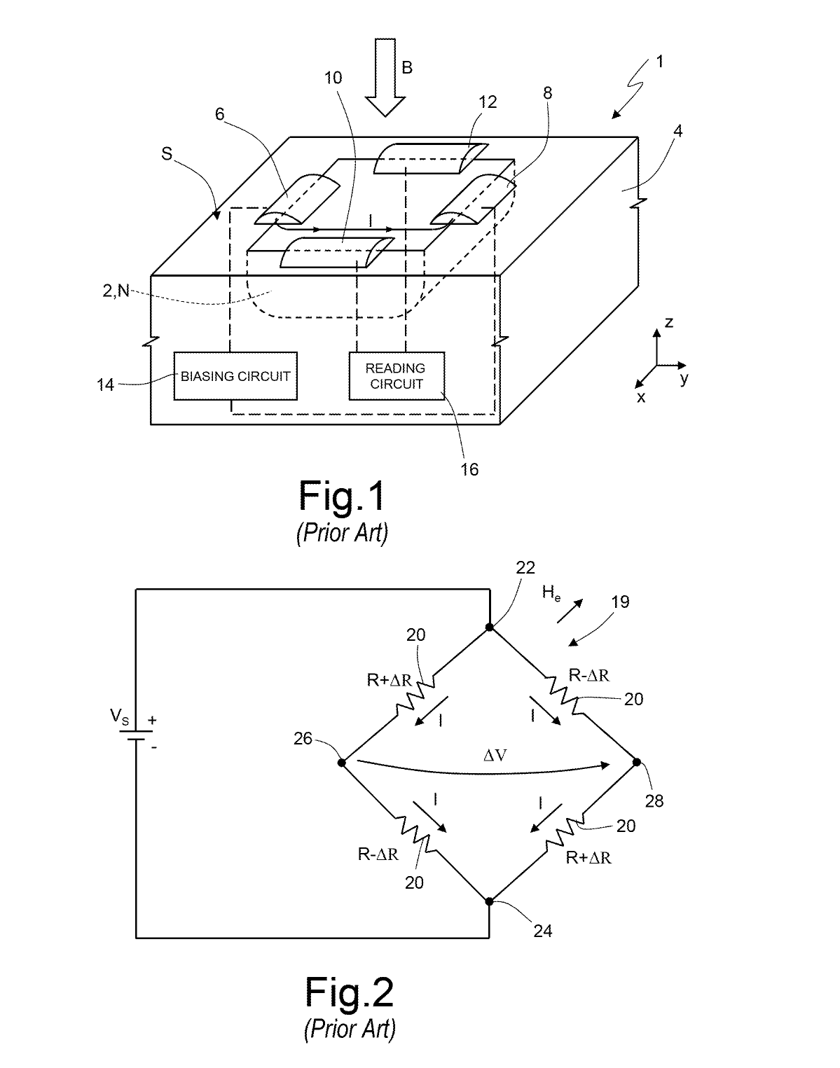

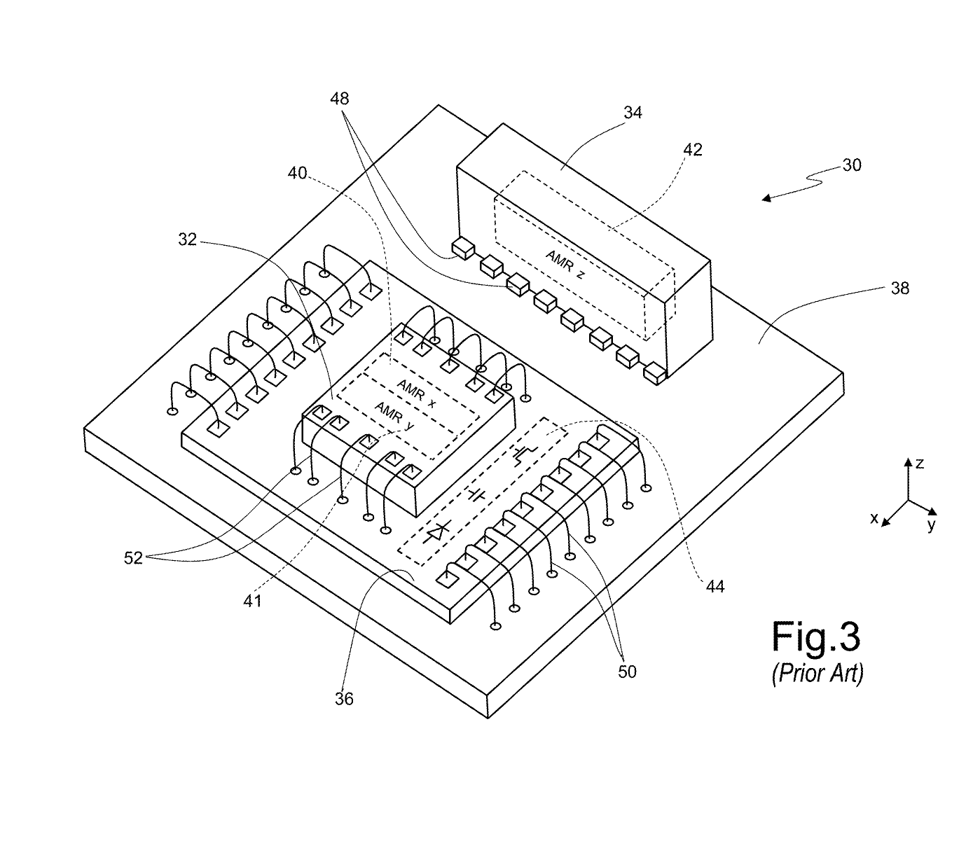

### DETAILED DESCRIPTION

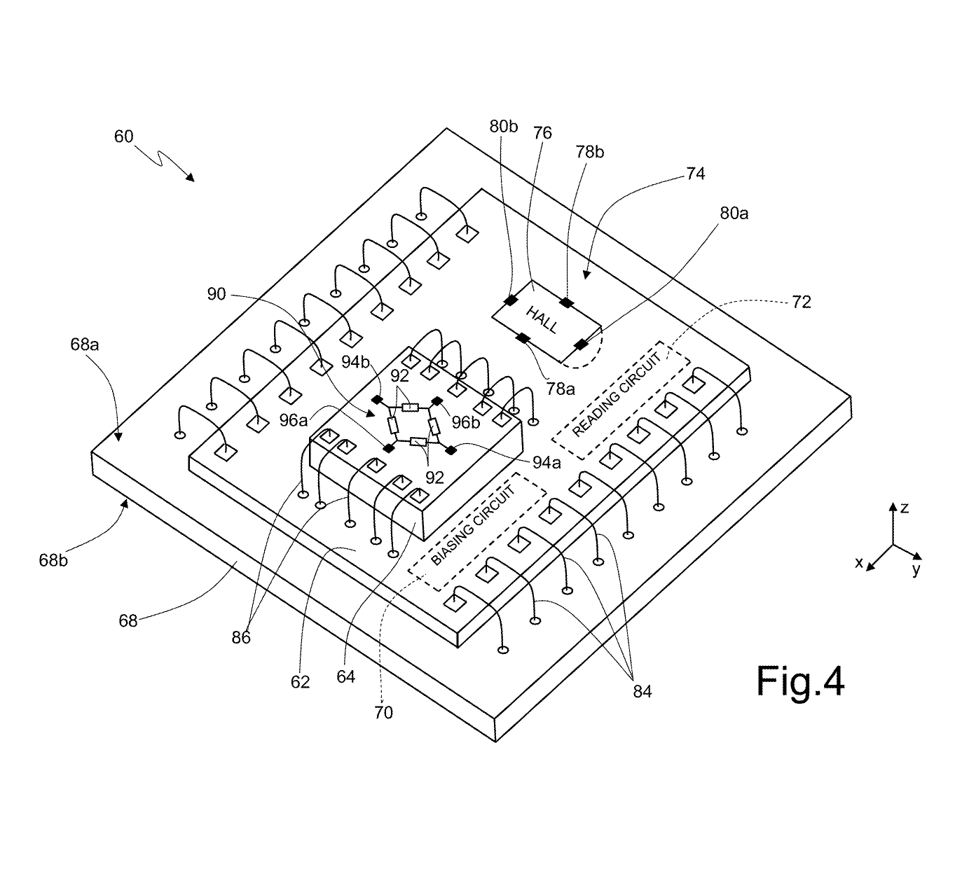

FIG. 4 shows a magnetic field sensor 60, which comprises a package (not shown), present inside which are a first die 62, a second die 64, and a support 68.

The support 68 has a top surface 68a and a bottom surface 68b, is made for example of organic resin, and includes vias and paths made of conductive material (not shown). In practice, the support 68 performs the function of carrying the first and second dice 62, 64, as well as the function of enabling electrical connection of the magnetic field sensor 60 with the outside world. For this purpose, the bottom surface 68b has a plurality of pads of conductive material, not shown.

In greater detail, formed within the first die 62 are an electronic supply circuit 70 and an electronic reading circuit 72, as well as a Hall transducer 74, i.e., a first electronic structure in itself known and designed to supply, when electrically supplied, a first electrical quantity that is a function of a possible first external magnetic field present in the proximity of the first electronic structure itself.

In a way in itself known, the Hall transducer 74 is formed by a well of semiconductor material 76, as well as by a first biasing terminal 78a and a second biasing terminal 78b, and by a first reading terminal 80a and a second reading terminal 80b. In addition, the aforementioned first electrical quantity may be a voltage present across the first and second reading terminals 80a, 80b. Furthermore, albeit not shown in FIG. 4, the electronic supply circuit 70 is electrically connected to the first and second biasing terminals 78a, 78b, and is hence able to supply the Hall transducer 74. In addition, albeit not shown in FIG. 4, the electronic reading circuit 72 is electrically connected to the first and second reading terminals 80a, 80b, and is hence able to receive the aforementioned first electrical quantity in order to process it as described hereinafter.

The second die 64 is arranged on the first die 62, with which it is in direct contact. In addition, the first die 62 is electrically connected to the support 68 by means of a plurality of first wire bondings 84. Likewise, the second die 64 is electrically connected to the first die 62 by means of a plurality of second wire bondings 86.

In greater detail, formed within the second die 64 is a first AMR transducer 90, i.e., a second electronic structure in itself known and designed to supply, when electrically supplied, a second electrical quantity that is a function of a possible second external magnetic field present in the proximity of the second electronic structure itself.

In particular, the first AMR transducer 90 may contain, in a way in itself known, four first magnetoresistive elements 92, electrically connected so as to form a Wheatstone bridge. In addition, the first AMR transducer 90 comprises a third biasing terminal 94a and a fourth biasing terminal 94b, and a third reading terminal 96a and a fourth reading terminal 96b. In addition, the aforementioned second electrical quantity may be a voltage present across the third and fourth reading terminals 96a, 96b.

Albeit not shown in FIG. 4, the electronic supply circuit 70 is moreover electrically connected to the third and fourth biasing terminals 94a, 94b, for example by means of the second wire bondings 86 and is hence able to supply the first AMR transducer 90. In addition, albeit not shown in FIG. 4, the electronic reading circuit 72 is electrically connected to the third and fourth reading terminals 96a, 96b, for example by means of the second wire bondings 86, and is hence able to receive the aforementioned second electrical quantity in order to process it as described hereinafter.

In greater detail, the electronic reading circuit 72 is designed to process, in a way in itself known, the first and second electrical quantities in order to generate a first electrical signal (analog or digital) and a second electrical signal (analog or digital), which indicate, respectively, a measure of the first external magnetic field and a measure of the second external magnetic field. In other words, the electronic supply circuit 70, the electronic reading circuit 72, and the Hall transducer 74 form a Hall sensor designed to detect the first external magnetic field. In addition, the electronic supply circuit 70, the electronic reading circuit 72, and the first AMR transducer 90 form a first AMR sensor designed to detect the second external magnetic field.

In still greater detail, the first and second dice 62, 64 and the support 68 have (to a first approximation) a parallelepipedal shape and each have two main surfaces, parallel to one another. In addition, the main surfaces of the first and second dice 62, 64 are parallel to the main surfaces of the support 68.

Assuming a reference system xyz, the mutually perpendicular axes x and y of which lie in a plane parallel to the main surfaces of the first and second dice 62, 64, and the axis z of which is perpendicular to the axes x and y, it is found that the first external magnetic field, to which the Hall transducer 74 is sensitive, is directed along the axis z. Moreover, the first magnetoresistive elements 92 of the first AMR transducer 90 are arranged in such a way that the second external magnetic field, to which the first AMR transducer 90 is sensitive, is directed alternatively along the axis x or else the axis y, and is thus perpendicular to the first external magnetic field.

In other words, the Hall sensor formed by the electronic supply circuit 70, by the electronic reading circuit 72, and by the Hall transducer 74 detects magnetic fields directed perpendicular with respect to the main surface of the first die 62. In addition, the first AMR sensor formed by the electronic supply circuit 70, by the electronic reading circuit 72, and by the first AMR transducer 90 detects magnetic fields directed parallel to the main surface of the second die 64.

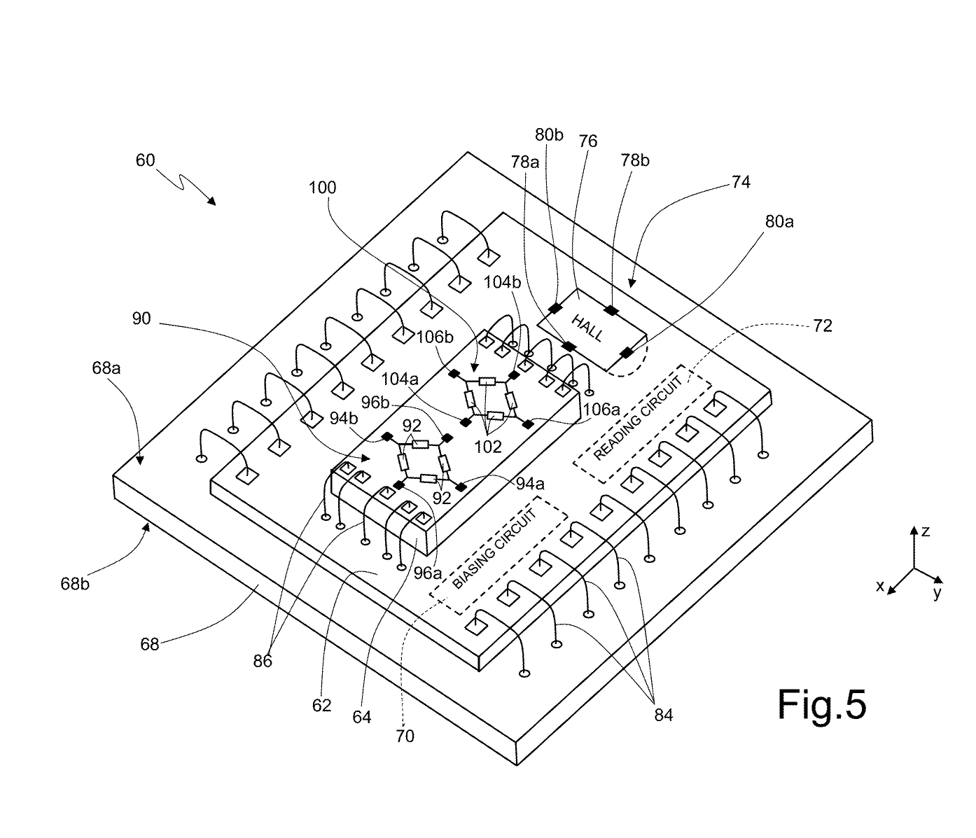

As shown in FIG. 5, it is likewise possible to form, within the second die 64, a second AMR transducer 100, which includes, for example, four second magnetoresistive elements 102, connected so as to form a further Wheatstone bridge. In a way in itself known, the second AMR transducer 100 may hence have a fifth biasing terminal 104a and a sixth biasing terminal 104b, as well as a fifth reading terminal 106a and a sixth reading terminal 106b. In particular, albeit not shown in FIG. 5, the fifth and sixth biasing terminals 104a, 104b are connected, for example by means of the second wire bondings 86, to the electronic supply circuit 70. In addition, the fifth and sixth reading terminals 106a, 106b are connected to the electronic reading circuit 72, for example by means of the second wire bondings 86.

In this embodiment, the electronic supply circuit 70, the electronic reading circuit 72 and the second AMR transducer 100 form a second AMR sensor designed to detect a third external magnetic field. In addition, the first and second magnetoresistive elements 92, 102, and consequently the third, fourth, fifth, and sixth biasing terminals 94a, 94b, 104a, 104b and the third, fourth, fifth, and sixth reading terminals 96a, 96b, 106a, 106b, are arranged in such a way that the second and third external magnetic fields are directed, respectively, along the axis x and the axis y, or vice versa.

Purely by way of example, it is hence possible for the third and fourth biasing terminals 94a, 94b to lie in a direction i) perpendicular to the direction in which the fifth and sixth biasing terminals 104a, 104b lie and ii) parallel to the direction in which the fifth and sixth reading terminals 106a, 106b lie. Likewise, once again purely by way of example, it is possible for the third and fourth reading terminals 96a, 96b to lie in a direction iii) perpendicular to the direction in which the fifth and sixth reading terminals 106a, 106b lie and iv) parallel to the direction in which the fifth and sixth biasing terminals 104a, 104b lie.

Irrespective of the details of embodiment, the first and second AMR sensors detect magnetic fields directed parallel to the main surface of the second die 64, but perpendicular to one another.

In practice, in the embodiment shown in FIG. 5, the magnetic field sensor 60 is a magnetic sensor of a triaxial type.

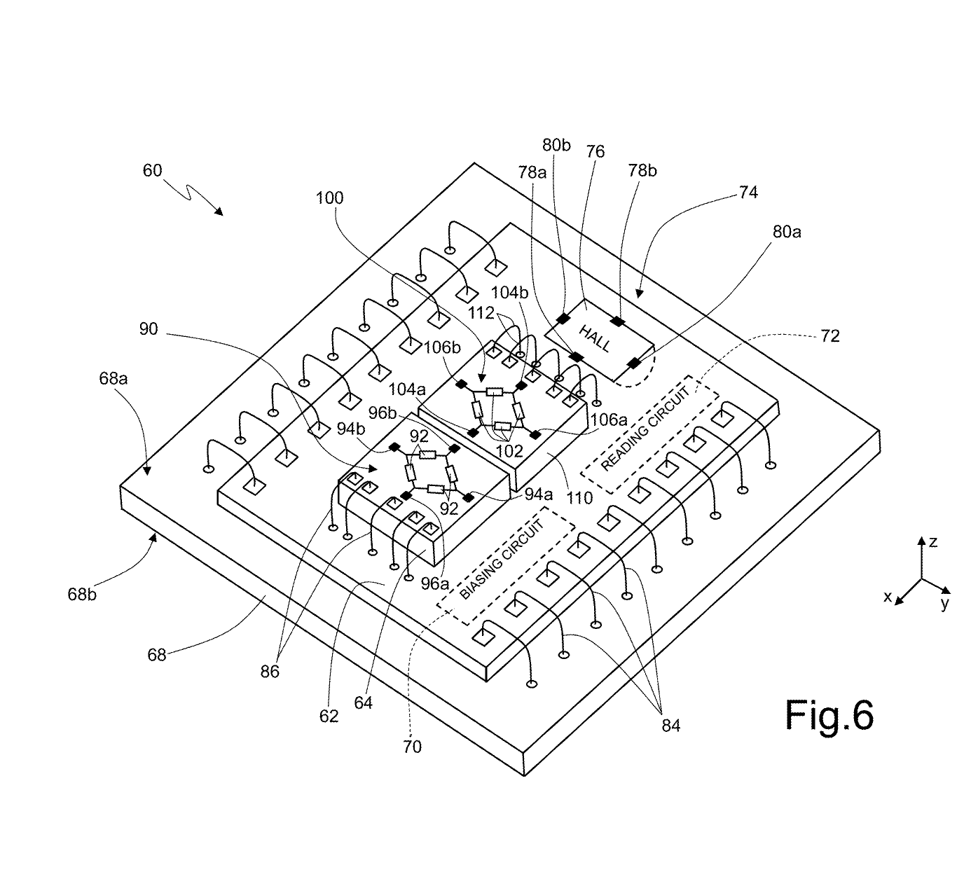

As illustrated in FIG. 6, likewise possible is a different embodiment, in which the magnetic field sensor 60 further comprises a third die 110, and in which the second AMR transducer 100 is formed within the third die 110. In particular, the third die 110 is carried by the first die 62, to which it is electrically connected by means of a plurality of third wire bondings 112.

The advantages of the present magnetic field sensor 60 emerge clearly from the above description.

In particular, thanks to the joined use of a Hall sensor and of one or more AMR sensors, a magnetic sensor sensitive along two or more axes is obtained, having contained overall dimensions and a high sensitivity.

In addition, the present magnetic sensor is easy to produce and industrialize.

Furthermore, the Hall sensor is integrated together with the electronic reading circuit in a single die, which may be obtained with technologies of a known type, such as for example CMOS or bipolar-CMOS-DMOS (double-diffused metal-oxide-semiconductor) technologies, the latter being generally known as BCD technologies.

Finally, it is clear that modifications and variations may be made to what has been described and illustrated herein, without thereby departing from the scope of protection of the present disclosure.

In particular, the second die 64 and possibly also the third die 110 may be arranged in a different way; for example, instead of being arranged on top of the first die 62, they may be arranged alongside the first die 62. Moreover, the electrical connections between the support 68, the first die 62, the second die 64, and possibly the third die 110 may be different from what has been illustrated and described. The support 68 itself may differ from the one described, and may even be absent. In addition, the first die 62, the second die 64, and possibly the third die 110 may be connected by means of the so-called “flip chip” technique.

As regards, instead, the Hall transducer 74, it may differ from what has been described. Moreover, it may have terminals different from the aforementioned first and second biasing terminals 78a, 78b, and first and second reading terminals 80a, 80b. Again, it may be formed by a plurality of wells made of semiconductor material, arranged so as to reduce the offset and increase the sensitivity of the Hall sensor.

Likewise, also the first and second AMR transducers 90, 100 may differ from what has been described; for example, they may each include just one magnetoresistive element, or else they may each include a number of magnetoresistive elements other than four. Once again, the magnetoresistive elements of each of the first and second AMR transducers 90, 100 may be connected so as to form circuits different from a Wheatstone bridge. Consequently, the first and second AMR transducers 90, 100 may have terminals different from the third and fourth biasing terminals 94a, 94b, the third and fourth reading terminals 96a, 96b, as well as the fifth and sixth biasing terminals 104a, 104b and the fifth and sixth reading terminals 106a, 106b. The very orientation of the first and second magnetoresistive elements 92, 102 within the second die 64, and possibly within the third die 110 (if present), may be different, in such a way that the first and second AMR transducers 90, 100 are sensitive to magnetic fields directed in a different way with respect to what has been described.

It is moreover possible for the first AMR transducer 90 and/or the second AMR transducer 100 to have components additional to the ones described, such as for example so-called “offset straps” and “set/reset straps”, which may be electronically controlled by the respective electronic supply circuit and/or by the respective electronic reading circuit.

In general, it is moreover possible for the electronic supply circuit 70 and the electronic reading circuit 72 to be arranged in a way different from what has been described.

Finally, each one from among the Hall transducer 74, the first AMR transducer 90, and the second AMR transducer 100 (if present) may be connected to a respective electronic supply circuit and to a respective electronic reading circuit, not necessarily formed within the first die 62.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A magnetic field sensor, comprising:
a first die having a first surface;
a second die having a second surface, the second die being fixed with respect to the first die, and the first and second surfaces being parallel to a reference plane;
a Hall magnetic sensor formed in the first die and configured to detect a first magnetic field having an orientation in a first direction perpendicular to the reference plane;
a first anisotropic magnetoresistive magnetic sensor including:
a first anisotropic magnetoresistive transducer formed in the second die configured to generate a first electrical measurement quantity as a function of a second magnetic field, the second magnetic field having an orientation in a second direction that is parallel to the reference plane; and
an electronic reading circuit formed in the first die, electrically connected to the first anisotropic magnetoresistive transducer, and configured to provide a first measure indicative of the second magnetic field based on the first electrical measurement quantity.

2. The magnetic field sensor according to claim 1, wherein the second die on top of the first die.

3. The magnetic field sensor according to claim 1, further comprising a second anisotropic magnetoresistive magnetic sensor that includes a second anisotropic magnetoresistive transducer configured to generate a second electrical detection quantity as a function of a third magnetic field having an orientation in a third direction parallel to said reference plane and perpendicular to said second direction.

4. The magnetic field sensor according to claim 3, wherein the electronic reading circuit is electrically connected to the second anisotropic magnetoresistive transducer and is configured to provide a second measure indicative of the third magnetic field based on the second electrical detection quantity.

5. The magnetic field sensor according to claim 3, wherein the second anisotropic magnetoresistive transducer is formed in the second die.

6. The magnetic field sensor according to claim 3, further comprising a third die, the second anisotropic magnetoresistive transducer is formed in the third die.

7. The magnetic field sensor according to claim 6, wherein said third die has a third surface parallel to said reference plane.

8. The magnetic field sensor according to claim 7, wherein the third die is on top of the first die.

9. The magnetic field sensor according to claim 1, further comprising a support, the first die being positioned on the support.

10. The magnetic field sensor according to claim 1, wherein the first anisotropic magnetoresistive transducer comprises a plurality of anisotropic magnetoresistive elements electrically connected as a Wheatstone-bridge circuit.

11. A device, comprising:
a support structure;
a first die on the support structure, the first die including:
a Hall effect sensor having a first and second biasing terminal and a first and second reading terminal;
a biasing circuit coupled to the first and second biasing terminal; and
a reading circuit coupled to the first and second reading terminal;
a second die on the first die, the second die including:
a first anisotropic magnetoresistive sensor having a third and fourth biasing terminal and a third and fourth reading terminal, the third and fourth biasing terminal being coupled to the biasing circuit and the third and fourth reading terminal being coupled to the reading circuit.

12. The device of claim 11 wherein the first anisotropic magnetoresistive sensor includes a first, second, third, and fourth magnetoresistive element.

13. The device of claim 12 wherein the first magnetoresistive element is coupled between the third biasing terminal and the third reading terminal, the second magnetoresistive element is coupled between the fourth biasing terminal and the third reading terminal, the third magnetoresistive element is coupled between the fourth biasing terminal and the fourth reading terminal, and the fourth magnetoresistive element is coupled between the third biasing terminal and the fourth reading terminal.

14. The device of claim 11 wherein the first anisotropic magnetoresistive includes four magnetoresistive elements arranged in a Wheatstone bridge.

15. The device of claim 11 wherein the biasing circuit and the reading circuit are coupled to the support.

16. The device of claim 15 wherein wirebonding couples the biasing circuit and the reading circuit to the support.

17. The device of claim 11 wherein in the second die further includes a second anisotropic magnetoresistive sensor.

18. The device of claim 17 wherein the second anisotropic magnetoresistive sensor includes:
a fifth and sixth biasing terminal coupled to the biasing circuit; and
a fifth and sixth reading terminal coupled to the reading circuit.

19. A method, comprising:
attaching a first die to a support structure, the first die including a Hall effect sensor having a first and second biasing terminal and a first and second reading terminal, a biasing circuit, and a reading circuit;
coupling the biasing circuit to the first and second biasing terminal;
coupling the reading circuit to the first and second reading terminal;
attaching a second die on the first die, the second die including a first anisotropic magnetoresistive sensor having a third and fourth biasing terminal and a third and fourth reading terminal;
coupling the third and fourth biasing terminal to the biasing circuit; and
coupling the third and fourth reading terminal being coupled to the reading circuit.

20. The method of claim 19 wherein coupling the third and fourth biasing terminal to the biasing circuit and coupling the third and fourth reading terminal to the reading circuit includes forming wirebonds between the second die and the first die.

21. The method of claim 19, further comprising coupling the first die to the support.

22. The method of claim 21 wherein coupling the first die to the support includes forming wirebonds between the first die and the support.
